(19) United States
(12) Patent Application Publication
(10) Pub. No.: US 2019/0334046 A1
(43) Pub. Date: Oct. 31, 2019

(54) SOLAR CELL MODULE

(71) Applicant: PANASONIC INTELLECTUAL PROPERTY MANAGEMENT CO., LTD., Osaka (JP)

(72) Inventors: Yoshimitsu IKOMA, Nara (JP); Motohiko SUGIYAMA, Osaka (JP); Naoki KURIZOE, Osaka (JP); Takeshi UEDA, Hyogo (JP)

(21) Appl. No.: 16/462,152

(22) PCT Filed: Feb. 2, 2018
(86) PCT No.: PCT/JP2018/003530

§ 371 Date: May 17, 2019

(30) Foreign Application Priority Data
Feb. 17, 2017 (JP) 2017-027651
Aug. 23, 2017 (JP) 2017-160202
Oct. 31, 2017 (JP) 2017-210188

(51) Int. Cl. H01L 31/048; H01L 31/05

(52) U.S. Cl. CPC H01L 31/048; H01L 31/0504

(57) ABSTRACT

A solar cell module that is one example of an embodiment of the present invention comprises: a plurality of solar cells; a wiring member for connecting adjacent solar cells together; a first protection substrate provided on the light-receiving-surface side of the solar cells; a second protection substrate provided on the rear-surface side of the solar cells; and an encapsulant layer for sealing the solar cells and provided between the first protection substrate and the second protection substrate. The first protection substrate is a resin substrate, and the linear expansion coefficient (α) of the encapsulant layer is 10-250 (10⁻⁶/K), and the tensile modulus of elasticity (E) thereof satisfies the condition in Formula 1:

140×exp(0.005α) MPa<E (Formula 1).

### TECHNICAL FIELD

The present disclosure relates to a solar cell module.

### BACKGROUND

A solar cell module includes a string of solar cells constructed by interconnecting a plurality of solar cells by a wiring member, two protection substrates holding the string, and an encapsulant layer provided between the protection substrates so as to seal the respective solar cells. In general, a glass substrate is used to form the protection substrates on the light-receiving-surface side of the solar cells. In recent years, however, for a lightweight configuration of a solar cell module, in some cases a resin substrate is used instead of a glass substrate. Patent Document 1 discloses a solar cell module that uses a resin substrate containing polycarbonate as its major component for a protection substrate on the light-receiving-surface side of the solar cells.

Also, Patent Document 1 discloses ethylene-vinyl acetate (EVA) copolymer as the resin for forming an encapsulant layer. For example, the encapsulant layer is placed in firm attachment to the protection substrates as well as the solar cells to constrain the movement of the cells and has a protection function for protecting the solar cells from moisture, etc.

### CITATION LIST

### Patent Literature

Patent Document 1: Japanese Unexamined Patent Application Publication No. 2013-145807

### SUMMARY

### Technical Problem

In the meantime, the temperature of a solar cell module changes significantly depending on its surrounding environment. When the change in the temperature of the solar cell module becomes large, the encapsulant layer experiences expansion and contraction, causing change in the intervals between the solar cells, which may lead to fracture of a wiring member interconnecting the cells. Such a problem should be conspicuous when a resin substrate is used as a protection substrate provided on the light-receiving-surface side of the solar cell.

### Solution to Problem

A solar cell module which is an aspect of the present disclosure includes a plurality of solar cells, a wiring member that connects adjacent ones of the solar cells, a first protection substrate provided on a light-receiving-surface side of the solar cells, a second protection substrate provided on a rear-surface side of the solar cells, and an encapsulant layer that is provided between the first protection substrate and the second protection substrate and seals the solar cells, where the first protection substrate is a resin substrate, a linear expansion coefficient (α) of the encapsulant layer is 10 to 250 (10⁻⁶/K), and a tensile modulus of elasticity (E) thereof satisfies a condition of Formula 1:

140×exp(0.005═) MPa<E (Formula 1)

### Advantageous Effects of Invention

According to the solar cell module as an aspect of the present disclosure, it becomes possible to prevent fracture of a wiring member which may occur due to the change in the temperature of the module. Specifically, even when the temperature of the solar cell module changes significantly, fracture of the wiring member can be suppressed to a satisfactory extent.

### BRIEF DESCRIPTION OF DRAWINGS

FIG. 1 is a plan view of a solar cell module as an example of an embodiment.

FIG. 2 is a diagram illustrating part of a cross section taken along the line AA in FIG. 1.

FIG. 3 is a diagram illustrating a simulation model of the solar cell module.

FIG. 4 is a diagram showing the relationship between physical properties of an encapsulant layer and an amount of change in a cell-to-cell distance.

FIG. 5 is a diagram illustrating a result of simulation which provides the basis for derivation of the expression of (Formula 1).

FIG. 6 is a diagram illustrating a modified example of a solar cell module as an example embodiment.

FIG. 7 is a diagram illustrating a modified example of a solar cell module as an example embodiment.

FIG. 8 is a cross-sectional view of a solar cell module as another example embodiment.

FIG. 9 is a cross-sectional view of a solar cell module as another example embodiment.

FIG. 10 is a cross-sectional view of a solar cell module as another example embodiment.

FIG. 11 is a cross-sectional view of a solar cell module as another example embodiment.

FIG. 12 is a cross-sectional view of a solar cell module as another example embodiment.

FIG. 13 is a diagram showing the relationship between a linear expansion coefficient and a tensile modulus of elasticity of an encapsulant layer (EVA) containing glass fibers.

### DESCRIPTION OF EMBODIMENTS

Example embodiments of a solar cell module according to the present disclosure will be described in detail below with reference to the drawings. As the drawings referred to in the embodiments are those that are schematically depicted, dimensions, proportions, etc. of the constituent elements depicted in the drawings should be determined taking into account the following explanations. It should be noted that the notation “a numerical value (A) to a numerical value (B)” which will appear in this specification is intended to indicate “not less than the numerical value (A) and not more than the numerical value (B)” unless otherwise indicated.

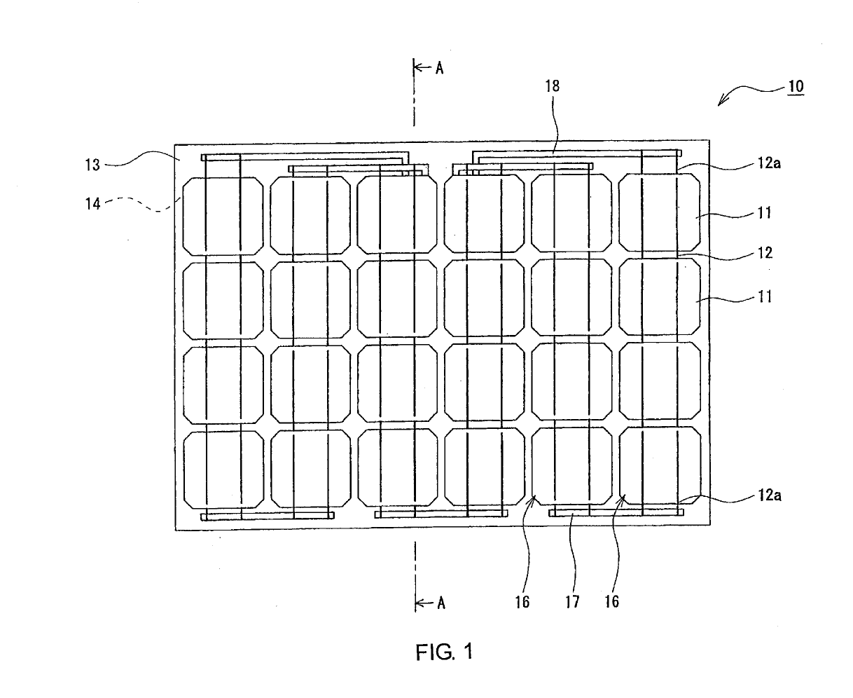

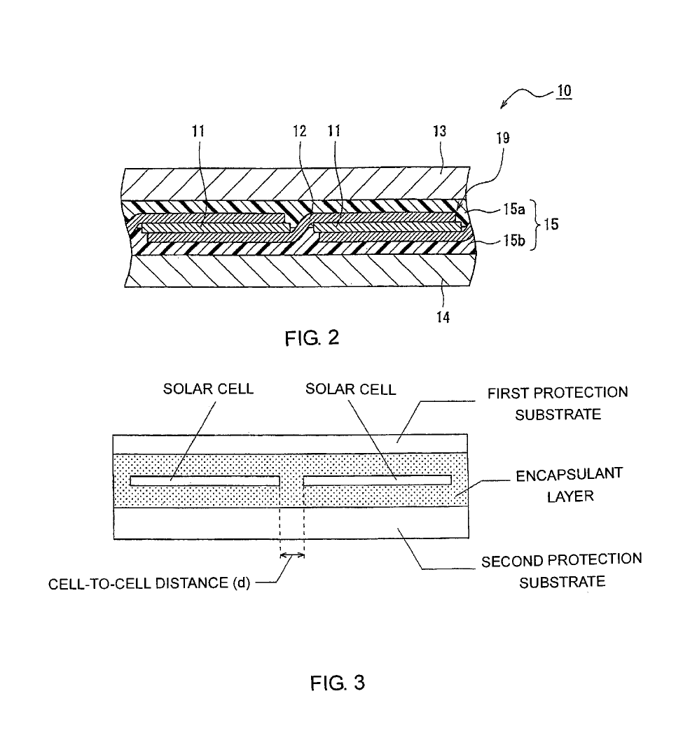

FIG. 1 is a plan view of a solar cell module 10 as an example of an embodiment and FIG. 2 is a diagram that illustrates part of a cross section taken along the line AA in FIG. 1. As illustrated in FIGS. 1 and 2, the solar cell module 10 includes a plurality of solar cells 11, a wiring member 12 that connects adjacent ones of the solar cells 11 to each other, a first protection substrate 13, and a second protection substrate 14. The first protection substrate 13, which is provided on the light-receiving-surface side of the solar cells 11, is a component that protects the light-receiving-surface side of the cells. The second protection substrate 14, which is provided on the rear-surface side of the solar cells 11, is a component that protects the rear-surface side of the cells. Also, the solar cell module 10 is provided between the first protection substrate 13 and the second protection substrate 14 and includes an encapsulant layer 15 that seals the solar cells 11.

Here, the “light-receiving surface” of the solar cell 11 refers to a surface that light predominantly enters and the “rear surface” refers to the surface on the opposite side of the light-receiving surface. Among the light beams entering the solar cells 11, more than 50% of these light beams, for example, 80% or more or 90% or more of them, enter the solar cells from the light-receiving-surface side. The terms “light-receiving surface” and “rear surface” are also used in the context of the solar cell module 10 and a photoelectric conversion part which will be described later.

As will be described later in detail, the encapsulant layer 15 is a resin layer whose linear expansion coefficient (α) is 10 to 250 (10⁻⁶/K) and whose tensile modulus of elasticity (E) satisfies the following expression of Formula 1:

140×exp(0.005α) MPa<E (Formula 1)

By using the encapsulant layer 15 that satisfies this condition, it becomes possible to reduce the change in the interval between the adjacent ones of the solar cell 11 (which will be hereinafter referred to as “cell-to-cell distance”) and suppress fracture of the wiring member 12 connecting the cells to each other in an advanced manner.

The solar cell module 10 illustrated in FIG. 1 has a rectangular shape when it is viewed in its plan view but its shape can be modified as appropriate, so that it may have a square shape, a pentagonal shape, etc. when viewed in its plan view. Also, a terminal box with a built-in bypass diode (not shown) may be provided on the rear-surface side of the solar cell module 10.

The solar cells 11 each include a photoelectric conversion part that generates carriers by receiving sunlight and a collector electrode that is provided on the photoelectric conversion part and collects the carriers. The photoelectric conversion part illustrated in FIG. 1 has a substantially square shape with four corners diagonally cut when viewed in its plan view.

As an example of the photoelectric conversion part, mention may be made of those that have a semiconductor substrate of crystalline silicon (Si), gallium arsenide (GaAs), indium phosphide (InP), etc.; an amorphous semiconductor layer formed on the semiconductor substrate; and a transparent conductive layer formed on the amorphous semiconductor layer. Specifically, a structure can be illustrated in which an i-type amorphous silicon layer, a p-type amorphous silicon layer, and a transparent conductive layer are formed in this order on one surface of an n-type monocrystalline silicon substrate and an i-type amorphous silicon layer, an n-type amorphous silicon layer, and a transparent conductive layer are formed in this order on the other surface of the substrate.

The collector electrode is made up of a light-receiving surface electrode formed on the light-receiving surface of the photoelectric conversion part and a rear surface electrode formed on the rear surface of the photoelectric conversion part. In this case, either one of the light-receiving surface electrode and the rear surface electrode serves as the n-side electrode and the other serves as the p-side electrode. It should be noted that the solar cells 11 may have the n-side and p-side electrodes only on the rear-surface side of the photoelectric conversion part. In general, a rear surface electrode is formed such that it has a larger surface than that of a light-receiving surface electrode, so that the rear surface of the solar cells 11 may be referred to as a surface whose area is larger of the collector electrodes, or a surface on which the collector electrode is formed. In this embodiment, it is assumed that a light-receiving surface electrode and a rear surface electrode are provided as the collector electrodes.

The collector electrode preferably includes a plurality of finger electrodes. Meanwhile, with regard to the rear surface electrode, it may be provided as an electrode that covers substantially the entire area of the rear surface of the photoelectric conversion part. The finger electrodes are thin line-shaped electrodes that are formed substantially in parallel with each other. The collector electrode may include a bus bar electrode having a width larger than that of the finger electrode and extending substantially at right angles to the finger electrodes. In a case where a bus bar electrode is provided, the wiring member 12 is mounted along the bus bar electrode.

The solar cells 11 are arranged between and held by the first protection substrate 13 and the second protection substrate 14 and sealed by the encapsulant layer 15 made of resin filling the space between the protection substrates. The solar cells 11 are arranged along the surfaces of the protection substrates so as to reside on the substantially same plane. It should be noted that the protection substrates are not limited to flat substrates and may be curved substrates. Adjacent ones of the solar cells 11 are connected in series to each other by the wiring member 12, whereby the string 16 of the solar cells 11 is formed. The wiring member 12 is typically called an interconnector or a tab.

The wiring member 12 is, for example, a rectangular-shaped wiring component and made of metal such as copper (Cu), aluminum (Al), etc. as its main component. The wiring member 12 may have a plating layer made of silver (Ag), nickel (Ni), or a low melting point alloy used as a solder, etc. as its main component. For example, the thickness of the wiring member 12 is 0.1 millimeters (mm) to 0.5 mm and the width thereof is 0.3 mm to 3 mm A plurality of the wiring members 12 (in general, two or three wiring members) are preferably attached to the light-receiving surface and the rear surface of the solar cells 11.

The wiring member 12 is arranged along the long side of the string 16 and provided so as to extend from one end of one solar cell 11 of adjacent ones of the solar cell 11 to the other end of the other solar cell 11. The length of the wiring member 12 is slightly shorter than the length obtained by adding the length of two solar cells 11 and the cell-to-cell distance. The wiring member 12 is bent in the direction of the thickness of the module between the adjacent ones of the solar cells 11 and joined to the light-receiving surface of the one solar cell 11 and the rear surface of the other solar cells 11 using resin adhesive or solder. In addition, the wiring member 12 is electrically connected to the collector electrodes of the solar cells 11.

The solar cell module 10 preferably has a plurality of the strings 16 on which the solar cells 11 are aligned in one row. Transition wiring members 17, 18 are provided on both sides of the strings 16 in the direction of the length thereof such that the transition wiring members 17, 18 are provided at a position where they do not overlap with the solar cells 11. The transition wiring member 17 is a wiring component that connects the strings 16 to each other. The transition wiring member 18 is a wiring component that connects, for example, the string 16 to an output wiring member. A wiring member 12a which is joined to the solar cell 11 positioned at the end of the string 16 is connected to the transition wiring members 17, 18.

The solar cell module 10 may include a frame that is mounted so as to conform to the peripheral edges of the first protection substrate 13 and the second protection substrate 14. The frame protects the peripheral portions of the protection substrates and is used when the solar cell module 10 is attached to a roof, etc. The solar cell module 10 may be a so-called frameless module that does not have a frame. A frameless module is implemented as an integrated module combining the solar cell module and the object to which the solar cell module is to be attached.

The first protection substrate 13, the second protection substrate 14, and the encapsulant layer 15 will now be described in detail below.

A transparent resin substrate is used as the first protection substrate 13. As described above, a resin substrate is preferably used as the first protection substrate 13 to ensure weight saving for the solar cell module 10. Meanwhile, in a case where a resin substrate is used as the first protection substrate 13, the impact resistance decreases as compared with a case where a glass substrate is used. Since a resin substrate has a lower hardness than that of a glass substrate, it is conceivable that the impact of a falling object such as hailstone causes deformation of the resin substrate and the force of impact is transferred to the solar cells 11, which may cause damage to the cells.

Also, if a glass substrate is used as the first protection substrate 13, expansion and contraction of the encapsulant layer 15 are suppressed by the glass substrate, so that the change in the cell-to-cell distance due to a change in the temperature of the module tends to be small, but the change in the cell-to-cell distance tends to be large when a resin substrate is used therefor. As a result, fracture of the wiring member 12 is likely to occur. Such a problem can be addressed by implementing as the encapsulant layer 15 a resin layer that satisfies the above-described condition of Formula 1 and, for example, using a second protection substrate 14 having a higher stiffness.

The resin substrate implemented as the first protection substrate 13 is made of at least one type of resin selected, for example, from polyethylene (PE), polypropylene (PP), cyclic polyolefin, polycarbonate (PC), polymethyl methacrylate (PMMA), polytetrafluoroethylene (PTFE), polystyrene (PS), polyethylene terephthalate (PET), and polyethylene naphthalate (PEN). An example of a suitable resin substrate is a resin substrate made of polycarbonate (PC) as its main component and, for example, a PC substrate whose PC content is 90 wt % or more, or 95 wt % to 100 wt %. Since PC is excellent in impact resistance and transparency, PC is suitable as a constituent material of the first protection substrate 13.

While the thickness of the resin substrate constituting the first protection substrate 13 is not limited to a particular value, the thickness is preferably 0.001 mm to 15 mm and more preferably 0.5 mm to 10 mm, considering impact resistance (protection of the solar cells 11), weight saving, optical transparency, etc. Note that the resin substrate may be referred to as resin substrate or resin film. In general, those having a large thickness are called resin substrate while those having a small thickness are called resin film, but in the context of the solar cell module 10 it is not necessary to clearly distinguish them from each other.

The tensile modulus of elasticity of the above-described resin substrate is not limited to a particular value but is preferably 1 GPa to 10 GPa and more preferably 2.3 GPa to 2.5 GPa in consideration of impact resistance, etc. The tensile modulus of elasticity (E) is computed by measuring the load (tensile stress) and elongation (strain) applied to a test piece under conditions of a test temperature of 25° C. and a test speed of 100 mm/min in accordance with JIS K7161-1 (“Plastics—Determination of tensile properties—Part 1: General principles”) and the following expression of Formula 2:

E=(σ2−σ1)/(ε2−ε1) (Formula 2)

where

σ1 is the tensile stress (Pa) measured with strain ε1=0.0005 and

σ2 is the tensile stress (Pa) measured with strain ε2=0.0025.

The total luminous transmittance of the above-described resin substrate is preferably high and is, for example, 80% to 100% or 85% to 95%. The total luminous transmittance is measured in accordance with JIS K7361-1 (“Plastics—Determination of the total luminous transmittance of transparent materials—Part 1: Single beam instrument”).

A transparent substrate may be used as the second protection substrate 14 in the same manner as the first protection substrate 13, and an opaque substrate may be used therefor if reception of light from the rear-surface side of the solar cell module 10 does not need to be taken into account. The total luminous transmittance of the second protection substrate 14 is not limited to a particular value and may be 0%. A glass substrate or metallic substrate may be used as the second protection substrate 14, but a resin substrate is preferably used to ensure weight saving for the solar cell module 10.

The resin substrate implemented as the second protection substrate 14 is made of at least one type of resin selected, for example, from cyclic polyolefin, polycarbonate (PC), polymethyl methacrylate (PMMA), polyether ether ketone (PEEK), polystyrene (PS), polyethylene terephthalate (PET), and polyethylene naphthalate (PEN). Also, the second protection substrate 14 may be made of fiber reinforced plastic (FRP). In particular, FRP is preferably used for applications that require impact resistance and weight saving.

As suitable FRPs, glass fiber reinforced plastic (GFRP), carbon fiber reinforced plastic (CFRP), aramid fiber reinforced plastic (AFRP), and the like may be mentioned. As the resin components constituting FRP, polyester, phenolic resin, epoxy resin, and the like can be illustrated.

The thickness of the second protection substrate 14 is not limited to a particular value but is preferably 5 μm or more. Also, if the second protection substrate 14 is made of FRP, the second protection substrate 14 has a thickness equal to or larger than a thickness corresponding to one fiber. When protection of the solar cells 11, weight saving thereof, etc. are taken into account, the thickness is preferably 0.1 mm to 10 mm and more preferably 0.2 mm to 5 mm. The thickness of the second protection substrate 14 is preferably equivalent to or larger than the thickness of the resin substrate constituting the first protection substrate 13.

The stiffness of the second protection substrate 14 is preferably higher than the stiffness of the first protection substrate 13. By defining the stiffness of the resin substrates as “(the stiffness of the) first protection substrate 13<(the stiffness of the) second protection substrate 14,” the position of the neutral plane shifts toward the rear-surface side (the side of the second protection substrate 14), so that the solar cells 11 can be placed at the position on the light-receiving-surface side relative to the neutral plane. It should be noted that, when a force of impact acts from the light-receiving-surface side of the solar cell module 10, compressive force acts on the light-receiving-surface side relative to the neutral plane while tensile force acts on the rear-surface side relative to the neutral plane. Since the solar cell 11 is more resistant to compressive force than tensile force, it becomes possible to suppress fracture of the solar cells 11 caused by the impact from the light-receiving-surface side by virtue of the solar cells 11 being located on the light-receiving-surface side relative to the neutral plane.

The stiffness (N·m²) of the substrate is expressed by “modulus of elasticity (GPa)×second moment of area (cm⁴).” The second moment of area (I) will be expressed, for example, by “I=width b (m)×thickness h (mm)³/12” if the cross section of the substrate has a plate-like shape.

Although the tensile modulus of elasticity of the second protection substrate 14 is not limited to a particular value, it is preferably 5 GPa to 120 GPa, which is higher than the tensile modulus of elasticity of the first protection substrate 13. The linear expansion coefficient of the second protection substrate 14 is, for example, 5 to 120 (10⁻⁶/K) and is preferably 5 to 30 (10⁻⁶/K). Meanwhile, the linear expansion coefficient of the first protection substrate 13 is, for example, 20 to 120 (10⁻⁶/K). The linear expansion coefficient of the second protection substrate 14 is preferably smaller than the linear expansion coefficient of the first protection substrate 13. The linear expansion coefficient is to be measured in accordance with JIS K7197.

The encapsulant layer 15, which is provided between the first protection substrate 13 and the second protection substrate 14 as described above, is a resin layer that seals the solar cells 11. The encapsulant layer 15 is placed in intimate attachment to the solar cells 11 to constrain displacement of the cells and seals the solar cells 11 such that they are not exposed to oxygen, water vapor, etc. In the mode illustrated in FIG. 2, the encapsulant layer 15 is in direct contact with the protection substrates and the solar cells 11. The solar cell module 10 has a multilayer structure in which, starting from the light-receiving-surface side, the first protection substrate 13, the encapsulant layer 15, the string 16 of the solar cells 11, the encapsulant layer 15, and the second protection substrate 14 are stacked in this order. It should be noted that all of the solar cells 11 are sealed by the encapsulant layer 15 in this embodiment but it is also possible to adopt a configuration where, for example, part of at least one of the solar cells 11 protrudes from the encapsulant layer 15.

The encapsulant layer 15 is made up of a first encapsulant layer 15a provided between the first protection substrate 13 and the solar cells 11 and a second encapsulant layer 15b provided between the second protection substrate 14 and the solar cells 11. The encapsulant layer 15 is preferably formed by a lamination process which will be described later using the resin substrate constituting the first encapsulant layer 15a and the resin substrate constituting the second encapsulant layer 15b. The same resin substrates may be used for the first encapsulant layer 15a and the second encapsulant layer 15b, or different resin substrates may be used therefor. If the compositions of the resin substrates are identical, the interface between the encapsulant layers cannot be confirmed depending on the specific cases.

The encapsulant layer 15 has a linear expansion coefficient (α) of 10 to 250 (10⁻⁶/K) and a tensile modulus of elasticity (E) which satisfies the condition of the expression of Formula 1:

140×exp(0.005═) MPa<E (Formula 1)

The first encapsulant layer 15a and the second encapsulant layer 15b which constitute the encapsulant layer 15 may differ from each other in linear expansion coefficient (α) and tensile modulus of elasticity (E), but the linear expansion coefficient (a) and the tensile modulus of elasticity (E) of these two layers need to satisfy the above-described condition. The tensile modulus of elasticity (E) of the encapsulant layer 15 can be obtained in the same manner as the tensile modulus of elasticity of the first protection substrate 13 in accordance with JIS K7161-1.

As described above, since the wiring member 12 has a small cross section in its width and is firmly joined to the solar cells 11, it is possible that a large stress acts upon a portion positioned between the cells and the portion may fracture when the encapsulant layer 15 experiences expansion and contraction due to a change in the temperature of the module or any other relevant factors and causes a change in the cell-to-cell distance. Traditionally, it has been accepted that, in a case where the encapsulant layer 15 with a high tensile modulus of elasticity is used, a large energy acts on the region between the cells when the encapsulant layer 15 exhibits expansion and contraction, which causes increase in the change in the cell-to-cell distance, so that the wiring member 12 is likely to fracture. However, as a result of the investigations by the inventors, it has been revealed that conversely the change in the cell-to-cell distance becomes smaller when the tensile modulus of elasticity of the encapsulant layer 15 is higher, and the stress acting upon the wiring member 12 can be reduced. In addition, with regard to the tensile modulus of elasticity of the encapsulant layer 15, the inventors have found the expression of E=140×exp(0.005α) (see FIG. 5 which will be discussed later) that defines the lower limit value and should be satisfied in order to suppress the fracture of the wiring member 12.

The expression of Formula 1 with regard to the tensile modulus of elasticity (E) of the encapsulant layer 15 is derived by using a simulation model of a solar cell module illustrated in FIG. 3 and obtaining an amount of change (Δd) in the cell-to-cell distance (d) under a thermal load condition, etc. which will be described later in accordance with a finite element technique. As illustrated in FIG. 3, this simulation model has a structure in which two solar cells are arranged between the first protection substrate and the second protection substrate on the same plane with a predetermined cell-to-cell distance (d) in between and the cells are sealed by an encapsulant layer that fills the space between the protection substrates.

In this simulation, the threshold for the amount of change (Δd) in the cell-to-cell distance was set to 60 micrometers (μm) in view of the actual values obtained in the temperature cycling tests on the solar cell module. The temperature cycling tests are tests that are conducted in conformity to JIS C8990:2009 (IEC61215:2005) (“Crystalline silicon terrestrial photovoltaic (PV) modules—Design qualification and type approval”). In a solar cell module, fracture of the wiring member 12 occurs with a high degree of probability when the amount of change (Δd) in the cell-to-cell distance becomes larger than 60 μm.

Analysis conditions for this simulation are described below. The physical properties of the first protection substrate, the second protection substrate, and the sealing layer in this simulation model are shown in Table 1. It is assumed here that polycarbonate is used to form the first protection substrate and glass fiber reinforced epoxy resin is used to form the second protection substrate.

Analysis software: Femtet (manufactured by Murata Software Co., Ltd.)
Use static analysis for stress analysis
Thermal load: 145° C. (stress-free temperature)->25° C.
Mesh shape: Tetra secondary element
Output amount of change (Δd) in the cell-to-cell distance (d) (μm)

TABLE 1

| | First Protection | Second Protection | Encapsulant |
|---|---|---|---|
| | Substrate | Substrate | Layer |
| Thickness (mm) | 1 | 3 | 0.6 |
| Linear Expansion | 70 | 20 | — |
| Coefficient (10⁻⁶/K) | | | |
| Tensile modulus of | 2.3 | 20 | — |
| elasticity (GPa) | | | |

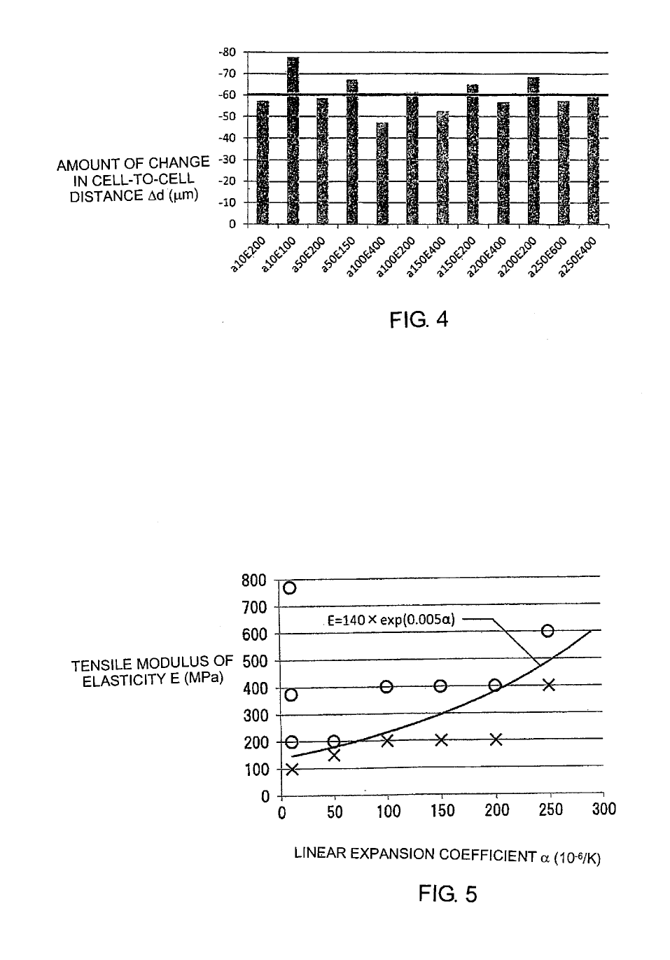

FIGS. 4 and 5 are diagrams that show the results of this simulation. FIG. 4 is a diagram that shows the amount of change (Δd) in the cell-to-cell distance observed when the linear expansion coefficient (α) and the tensile modulus of elasticity (E) of the encapsulant layer are changed. It should be noted that, in this simulation, the encapsulant layer contracts due to decease in the temperature causing the cell-to-cell distance (d) to become smaller, so that the amount of change (Δd) is indicated by negative values. FIG. 5 is a diagram that shows the relationship between the linear expansion coefficient (α) and the tensile modulus of elasticity (E) of the encapsulant layer, where the point at which fracture of the wiring member 12 is likely to occur is indicated by (x) and the point at which the fracture is less likely to occur is indicated by (◯). The point at which fracture of the wiring member 12 is likely to occur is a point where the amount of change (Δd) exceeds the above-described threshold.

As a result of this simulation, as illustrated in FIG. 4, it has been revealed that, if the linear expansion coefficient (α) assumes the same value, a larger tensile modulus of elasticity (E) leads to a smaller amount of change (Δd) in the cell-to-cell distance. In addition, as shown in FIG. 5, it has also been revealed that, when the tensile modulus of elasticity (E) of the encapsulant layer becomes lower than or equal to the curve defined by E=140×exp(0.005α) as a boundary, then the amount of change (Δd) in the cell-to-cell distance exceeds the threshold (60 μm) and the fracture of the wiring member 12 tends to occur more easily.

In other words, when the tensile modulus of elasticity (E) of the encapsulant layer becomes higher than the curve defined by E=140×exp(0.005α) as a boundary (that is, when the condition of Formula 1 is satisfied), then the amount of change (Δd) in the cell-to-cell distance is suppressed and the probability of the fracture of the wiring member 12 is lowered. It should be noted that the result of this simulation is established with accuracy in the case where the linear expansion coefficient α is 10 to 250 (10⁻⁶/K). Accordingly, the fracture of the wiring member 12 can be suppressed in a satisfactory manner by using the encapsulant layer 15 that has the linear expansion coefficient (α) of 10 to 250 (10⁻⁶/K) and the tensile modulus of elasticity (E) satisfying the condition of Formula 1.

The upper limit value of the tensile modulus of elasticity (E) of the encapsulant layer 15 is not limited to a particular value in view of the suppression of the fracture of the wiring member 12 but is preferably less than 1000 MPa in view of breakage of cells at the time of manufacturing of the solar cells 11 by the encapsulant layer 15. Specifically, the tensile modulus of elasticity (E) of the encapsulant layer 15 preferably satisfies the condition of the following expression of Formula 3:

140×exp(0.005α) MPa<E<1000 MPa (Formula 3)

While the resin implemented as the encapsulant layer 15 is not limited to a particular one as long as it satisfies the expression of Formula 3, polyolefin, alicyclic polyolefin, ethylene acrylic acid ester copolymer, polyvinyl butyral, ionomer, epoxy resin, alicyclic epoxy resin, etc. may be mentioned, because solar cell modules used outdoors should have weatherability.

The total luminous transmittance of the first encapsulant layer 15a is preferably high and is, for example, 80% to 100% or 85% to 95%. Meanwhile, the total luminous transmittance of the second encapsulant layer 15b is not limited to a particular value. If reception of light from the rear-surface side of the solar cell module 10 does not need to be taken into account, the second encapsulant layer 15b may contain color materials such as white pigment and black pigment and the total luminous transmittance may be 0%.

The thickness of the encapsulant layer 15 (the sum of the thickness of the first encapsulant layer 15a and the thickness of the second encapsulant layer 15b) is not limited to a particular value but is preferably 0.5 mm to 5 mm and more preferably 0.5 mm to 2 mm in consideration of the sealing property of the solar cells 11, transparency, etc. As illustrated in FIG. 2, the thicknesses of the first encapsulant layer 15a and the second encapsulant layer 15b may be substantially identical with each other. In this case, examples of the thicknesses of the first encapsulant layer 15a and the second encapsulant layer 15b will be 0.3 mm to 1.5 mm or 0.3 mm to 1 mm.

Here, the thickness of the encapsulant layer 15 means the maximum length in the direction of the thickness of the solar cell module 10 from the surface (interface) of the encapsulant layer 15 on the side of the first protection substrate 13 to the surface (interface) thereof on the side of the second protection substrate 14. The same applies to the thicknesses of the first encapsulant layer 15a and the second encapsulant layer 15b. If only the encapsulant layer 15 and the string 16 exist between the protection substrates, then the interval between the protection substrates agrees with the thickness of the encapsulant layer 15.

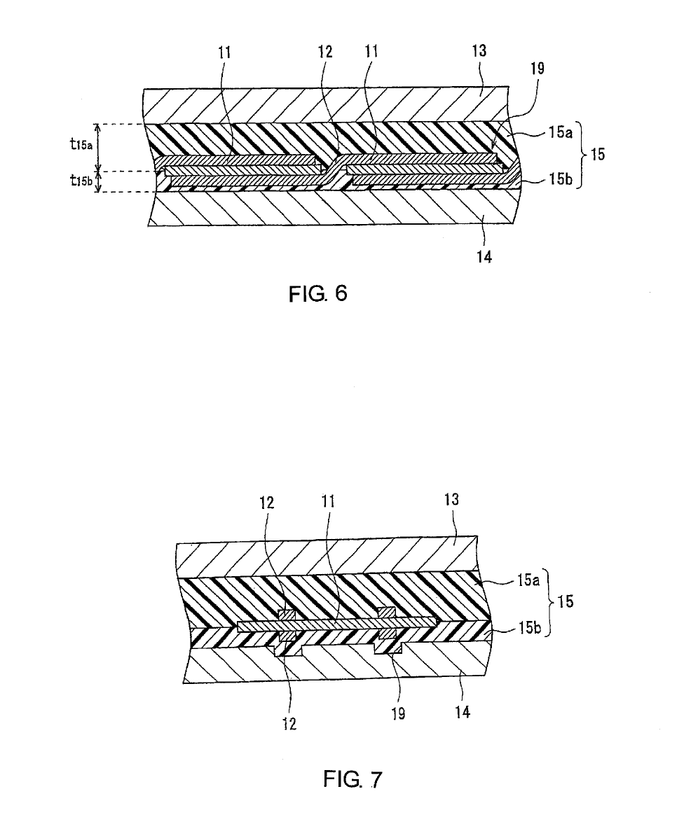

As illustrated in FIG. 6, the thickness t_{15b} of the second encapsulant layer 15b may be smaller than the thickness t₁₅ₐ of the first encapsulant layer 15a. Specifically, the encapsulant layer 15 may have the thickness between the second protection substrate 14 and the solar cells 11 which is smaller than the thickness between the first protection substrate 13 and the solar cells 11. By defining the thickness of the encapsulant layer 15 such that thickness t_{15b}<thickness t₁₅ₐ, the solar cells 11 can be made close to the second protection substrate 14 having the high stiffness and the small linear expansion coefficient, and the stress acting on the solar cell 11 and the wiring member 12 can be reduced. In this case, an example of a suitable thickness t₁₅ₐ of the first encapsulant layer 15a is 0.5 mm to 2 mm. The thickness t_{15b} of the second encapsulant layer 15b is preferably small within the range where there is no hindrance to the sealing property of the solar cells 11, etc. and may be smaller than the thickness of the wiring member 12. An example of the suitable thickness t_{15b} is 0.05 mm to 0.5 mm.

As illustrated in FIG. 7, the second protection substrate 14 may have a recess 19 that is formed in the second protection substrate 14 such that the recess 19 is provided at a location where it is in alignment with the wiring member 12 provided on the rear-surface side of the solar cells 11 in the direction of the thickness of the solar cell module 10. Since the wiring member 12 is joined to the rear surface of the solar cells 11, it is difficult to make the solar cell 11 close to the second protection substrate 14 if the surface of the second protection substrate 14 oriented toward the side of the solar cell 11 is flat. Meanwhile, by providing the recess 19, the influence of the thickness of the wiring member 12 can be mitigated. Specifically, by providing the recess 19, the thickness t_{15b} of the second encapsulant layer 15b can be made smaller and the solar cell 11 can be made close to the second protection substrate 14.

A plurality of the recesses 19 are preferably formed so as to correspond to the wiring members 12 joined to the rear surface of the solar cells 11. The recess 19 is formed in the direction of the length of the string 16 and may be formed with a length exceeding the total length of the string 16. With regard to the depth of the recess 19, the above-described effect can be obtained even when the depth is smaller than the depth corresponding to the thickness of the wiring member 12, but the depth is preferably equal to or larger than a depth corresponding to the thickness of the wiring member 12. An example of the suitable recess 19 is 0.1 mm to 0.5 mm. Also, the width of the recess 19 may be smaller than the width of the wiring member 12 but is preferably larger than the width of the wiring member 12 such that the positional displacement of the wiring member 12 and the recess 19 relative to each other can be accommodated to a certain extent. An example of the suitable width of the recess 19 is 0.3 mm to 5 mm.

The solar cell module 10 that has the above-described features can be manufactured by laminating the string 16 of the solar cells 11 using the first protection substrate 13, the second protection substrate 14, the resin substrate constituting the first encapsulant layer 15a, and the resin substrate constituting the second encapsulant layer 15b. In the lamination process, the first protection substrate 13, the resin substrate constituting the first encapsulant layer 15a, the string 16, the resin substrate constituting the second encapsulant layer 15b, and the second protection substrate 14 are stacked in this order upon a heater. This layered product is heated in a state of vacuum at about 150° C., for example. At this point, the resin substrates constituting the first encapsulant layer 15a and the second encapsulant layer 15b are melted or softened and brought into firm attachment to the string 16 and the protection substrates, as a result of which the solar cell module 10 having the cross-sectional structure as illustrated in FIG. 2 can be obtained. After that, a terminal box, a frame, etc. may be mounted thereto as required.

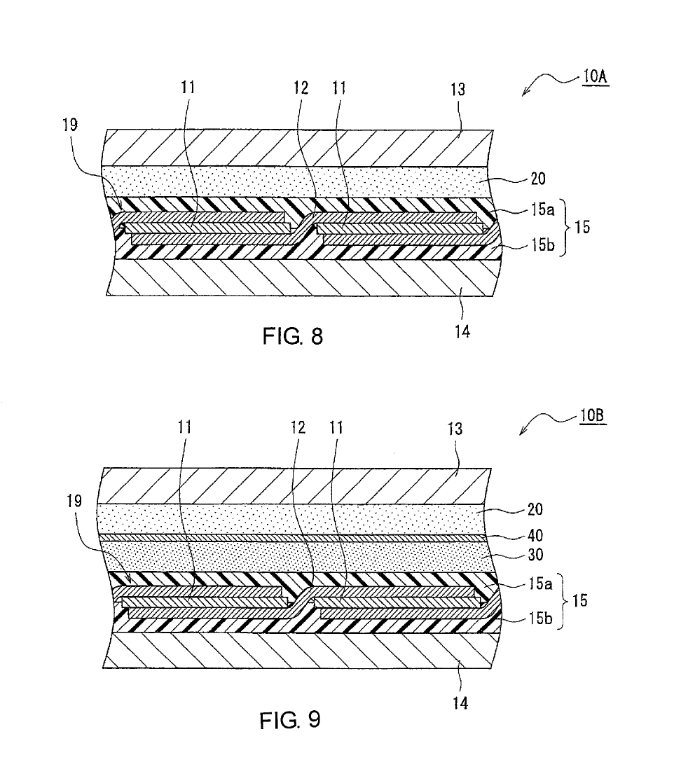

It should be noted that improvements may be made to the above-described embodiment by providing an additional layer between the first protection substrate 13 and the encapsulant layer 15 as illustrated in FIGS. 8 and 9. FIGS. 8 and 9 are cross-sectional views of the solar cell module corresponding to FIG. 2. In the following description, the same reference numerals are used for the same constituent elements as those in the above-described embodiment, redundant explanations will not be repeated, and the differences from the above-described embodiment will mainly be described. It should be noted that it is assumed as a matter of course that the constituent elements of multiple embodiments and modified examples described in this specification may be selectively combined.

The solar cell module 10A illustrated in FIG. 8 differs from the solar cell module 10 in that it has a buffer layer 20 between the first protection substrate 13 and the encapsulant layer 15, where the transverse elasticity modulus of the buffer layer 20 is equal to or less than 0.1 MPa. The buffer layer 20 has a function for mitigating the load acting upon the solar cell 11 caused by thermal expansion of the first protection substrate 13, deformation of the first protection substrate 13 due to collision with a falling object, or any other factors and suppressing damage to the solar cells 11. Also, by providing the buffer layer 20, the stress acting upon the wiring member 12 can be reduced and the fracture of the wiring member 12 can be more effectively suppressed.

The solar cell module 10A has a structure in which, starting from the light-receiving-surface side, the first protection substrate 13, the buffer layer 20, and the encapsulant layer 15 are stacked in this order, but the arrangement of the individual layers is not limited to this. For example, it may have a multilayer structure in which the buffer layer 20 is sandwiched by encapsulant layers 15.

The buffer layer 20 is preferably made of transparent and highly flexible resin. The buffer layer 20 may be made of gel-like resin and may be made of hydrogel containing water or organogel containing organic solvent. The buffer layer 20 is composed using at least one type selected, for example, from acrylic gel, urethane gel, and silicone gel. Amongst others, silicone gel which excels in durability should preferably be used.

The total luminous transmittance of the buffer layer 20 is preferably high and, for example, is 80% to 100% or 85% to 95%. The thickness of the buffer layer 20 is not limited to a particular value and is preferably 0.1 mm to 10 mm or less and more preferably 0.2 mm to 1.0 mm or less in consideration of protection of the solar cells 11, optical transparency, etc.

The transverse elasticity modulus of the buffer layer 20 is equal to or less than 0.1 MPa as described above and is preferably 0.001 MPa to 0.1 MPa. When the transverse elasticity modulus of the buffer layer 20 falls within this range, it is possible to obtain the above-described stress mitigation effect while ensuring the mechanical strength, manufacturing characteristics, etc. that the solar cell module 10 should have. The transverse elasticity modulus is measured using a rheometer.

The solar cell module 10B illustrated in FIG. 9 differs from the solar cell module 10A in that it includes a reinforcing layer 30 between the first protection substrate 13 and the encapsulant layer 15, where the linear expansion coefficient of the reinforcing layer 30 is 0 to 150 (10⁻⁶/K). Further, the solar cell module 10B includes a gas barrier layer 40 whose oxygen permeability is equal to or less than 200 cm³/m²·24 h·atm. The solar cell module 10B has a structure in which, starting from the light-receiving-surface side, the first protection substrate 13, the buffer layer 20, the gas barrier layer 40, the reinforcing layer 30, and the encapsulant layer 15 are stacked in this order and the string 16 is sandwiched by the reinforcing layer 30 and the second protection substrate 14 via the encapsulant layer 15.

The reinforcing layer 30 has the function for suppressing the expansion and contraction of the encapsulant layer 15 and reducing the stress acting on the wiring member 12 in the same manner as the second protection substrate 14. The linear expansion coefficient of the reinforcing layer 30 is 0 ppm to 150 ppm as described above and is preferably 0 ppm to 30 ppm. The reinforcing layer 30 may have a linear expansion coefficient and a tensile modulus of elasticity equivalent to those of the second protection substrate 14.

The reinforcing layer 30 is preferably made of a transparent resin substrate. The resin substrate implemented as the reinforcing layer 30 may be made of the same or similar resin as the resin constituting the first protection substrate 13. For the reinforcing layer 30, for example, a uniaxially or biaxially stretched polyethylene terephthalate (PET) substrate may be used.

The total luminous transmittance of the reinforcing layer 30 is preferably high and, for example, is 80% to 100% or 85% to 95%. The thickness of the reinforcing layer 30 is not limited to a particular value but is preferably 10 μm to 200 μm in consideration of suppression of the fracture of the wiring member 12, optical transparency, etc.

The gas barrier layer 40 is a layer with a lower oxygen permeability than that of the first protection substrate 13 and has the suppression function for suppressing the oxygen permeating the first protection substrate 13 from acting upon the solar cell 11. It should be noted that the gas barrier layer 40 has the blocking function for blocking not only oxygen but also water vapor, etc. In a case where a resin substrate is used as the first protection substrate 13, the amount of oxygen permeation increases as compared with a case where a glass substrate is used therefor, but the amount of oxygen permeation from the side of the first protection substrate 13 can be reduced by providing the gas barrier layer 40. In the example illustrated in FIG. 9, the gas barrier layer 40 is formed on the surface of the reinforcing layer 30 oriented toward the side of the first protection substrate 13, but the arrangement of the gas barrier layer 40 is not limited to this, and, for example, the gas barrier layer 40 may be formed on the surface of the first protection substrate 13 oriented to the side of the solar cells 11.

The gas barrier layer 40 is preferably made of an inorganic compound such as silicon oxide (silica), aluminum oxide (alumina), etc. but may be a resin layer that can achieve oxygen permeability equal to or lower than 200 cm³/m²24 h·atm. An example of the suitable gas barrier layer 40 is a vapor-deposited layer such as silica formed on the surface of the reinforcing layer 30. Also, a vapor-deposited layer such as silica may be formed on the surface of the first protection substrate 13 oriented toward the side of the solar cell 11. The oxygen permeability of the gas barrier layer is measured in accordance with JIS K7126.

The total luminous transmittance of the gas barrier layer 40 is preferably high and, for example, is 80% to 100% or 85% to 95%. The thickness of the gas barrier layer 40 is not limited to a particular value but is preferably 0.1 μm to 10 μm in consideration of gas barrier property, optical transparency, etc.

It should be noted that it is possible to add other functional layers in addition to the buffer layer 20, the reinforcing layer 30, and the gas barrier layer 40. For example, a transparent gas barrier layer may be formed on the second protection substrate 14 and a metal layer containing aluminum or the like as a main component may be formed. The metal layer has the shielding function against oxygen, water vapor, etc. and also functions as a reflective layer that redirects the light transmitted through the solar cells 11 or between the cells back to the side of the solar cells 11.

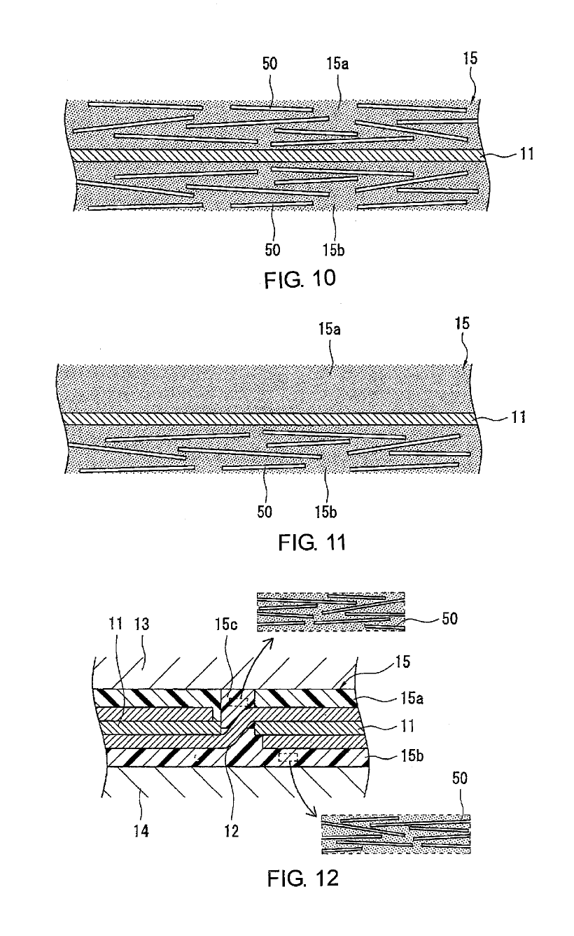

As illustrated in FIGS. 10 to 12, the encapsulant layer 15 may contain fillers 50 whose aspect ratio is greater than 1. The encapsulant layer 15 preferably contains the fillers 50 by 1 to 30 vol % with respect to the volume of the layer. The content of the fillers 50 is more preferably 1 to 10 vol %, and 1 to 5 vol % is in particular preferable. A suitable filler 50 has a modulus of elasticity of 3 GPa or more and a linear expansion coefficient of 20 ppm or less. By adding these fillers 50 to the encapsulant layer 15, it becomes possible to ensure low thermal expansion for the encapsulant layer 15 in particular in the direction of the length of the fillers 50 and reduce the change in the cell-to-cell distance.

Long fiber fillers with a high aspect ratio are suitable as the fillers 50. The aspect ratio of the filler 50 is preferably 2 or more or more preferably 5 or more, and 10 or more is particularly preferable. The average value of the aspect ratio is, for example, 10 to 1000. The aspect ratio of the filler 50 is computed by dividing the fiber length of the filler 50 by the fiber diameter thereof, and the average value thereof is computed with regard to 100 fillers 50 randomly selected from the encapsulant layer 15. The fiber length and the fiber diameter of the filler 50 are obtained by observation of the encapsulant layer 15 using an optical microscope.

A plurality of the fillers 50 are dispersed in the encapsulant layer 15 and are oriented in the direction defined by the surface of the encapsulant layer 15 (the direction orthogonal to the direction of the thickness). Specifically, the fillers 50 exist in the encapsulant layer 15 in a state where the direction of the length of the fiber extends in the direction of the surface rather than the direction of the thickness of the encapsulant layer 15. At least one of the fillers 50 preferably has a longer fiber length than the thickness of the encapsulant layer 15. By making the fiber length of the filler 50 greater than the thickness of the encapsulant layer 15, the direction of the length of the fiber will be more easily oriented in the direction of the surface of the encapsulant layer 15. The fillers 50 may be oriented in the direction of the length of the string 16 and the direction of the length of the fibers may be in the direction of the length of the string 16. In this case, the effect of suppression of the fracture of the wiring member 12 is enhanced. For example, the orientation directions of the fillers 50 can be aligned by uniaxially stretching the resin substrate containing the fillers 50.

The average fiber length of the fillers 50 is preferably greater than the thickness of the encapsulant layer 15. The average fiber length is computed, as described above, by measuring the fiber lengths of 100 fillers 50 randomly selected from the encapsulant layer 15 and averaging the measured values. If the encapsulant layer 15 is constituted by the first encapsulant layer 15a and the second encapsulant layer 15b and the fillers 50 are included in these layers, then, for example, at least one length, or preferably an average fiber length, of the fillers 50 included in the first encapsulant layer 15a is greater than the thickness of the first encapsulant layer 15a. Likewise, at least one length, or preferably an average fiber length, of the fillers 50 included in the second encapsulant layer 15b is greater than the thickness of the second encapsulant layer 15b.

As examples of the filler 50, mention may be made of glass fiber, carbon fiber, metal fiber, rock wool, ceramic fiber, slag fiber, potassium titanate whisker, boron whisker, aluminum borate whisker, calcium carbonate whisker, and titanium oxide whisker. Also, the fillers 50 may be resin fibers such as cellulose fiber, aramid fiber, boron fiber, polyethylene fiber, etc. Meanwhile, the modulus of elasticity is preferably 3 GPa or more and the linear expansion coefficient is preferably 20 ppm or less, and the modulus of elasticity is more preferably 10 GPa or more and the linear expansion coefficient is more preferably 10 ppm or less.

Also, the fillers 50 are preferably insulating. Glass fibers whose average fiber length is greater than the thickness of the encapsulant layer 15 are particularly preferable as an example of the suitable fillers 50. The glass fibers have, for example, a modulus of elasticity of 50 GPa or more and a linear expansion coefficient of 10 ppm or less. By using glass fibers to implement the fillers 50, significantly low thermal expansion can be achieved for the encapsulant layer 15, but it is possible that voltage induced output reduction (PID) may occur due to diffusion of Na contained in the glass. If glass fibers are to be used, the encapsulant layer 15 is preferably made of polyolefin resin such as PE, PP, cyclic polyolefin, etc. By using polyolefin resin, diffusion of Na can be suppressed.

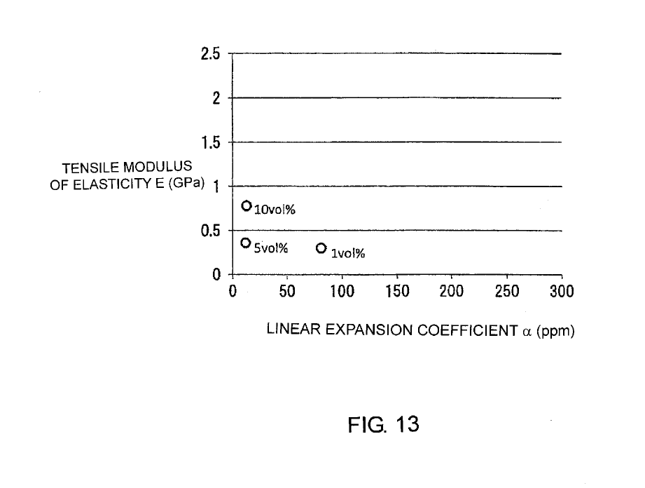

A low-α and highly elastic encapsulant layer 15 can be created by dispersing, for example, by using a stirring machine such as a plastic mill, glass fibers (ECS06-670 manufactured by Central Glass Co., Ltd.) by, for example, 1 vol %, 5 vol %, and 10 vol %, as shown respectively in FIG. 13, into the ethylene-vinyl acetate copolymer (Evaflex 450 manufactured by Dupont-Mitsui Polychemicals Co., Ltd.) which is the resin constituting the encapsulant layer 15, and forming a sheet therefrom by a press machine, etc.

As illustrated in FIG. 10, the fillers 50 are preferably contained at least in the second encapsulant layer 15b and may be contained in both of the first encapsulant layer 15a and the second encapsulant layer 15b. In this case, in order to suppress optical diffusion of the fillers 50 in the first encapsulant layer 15a, refractive indices of the resins that constitute the first encapsulant layer 15a and the fillers 50 are preferably adjusted so as to be of the same degree. In the mode illustrated in FIG. 10, the amount of the fillers 50 dispersed in the first encapsulant layer 15a may be made smaller than the amount of the fillers 50 dispersed in the second encapsulant layer 15b.

As illustrated in FIG. 11, there can be adopted a configuration in which the fillers 50 are contained only in the second encapsulant layer 15b. In this case, the light incident on solar cell 11 from the light-receiving-surface side does not decrease due to the diffusion by the fillers 50, so that the change in the cell-to-cell distance can be made small while a favorable power generation efficiency is maintained. The fillers 50 such as glass fibers may exist in the gap between the solar cells 11 where the interface between the first encapsulant layer 15a and the second encapsulant layer 15b exists such that the fillers 50 do not protrude to the light-receiving-surface side of the solar cell 11. Since the fillers 50 exist in the gap between the adjacent ones of the solar cells 11, changes in the cell-to-cell distance can be more readily suppressed.

As illustrated in FIG. 12, the fillers 50 may exist on the side of the first protection substrate 13 relative to the solar cells 11 in the range in which they are in alignment with the gap between the solar cells 11 in the direction of the thickness of the module. It should be noted that the fillers 50 are not contained in the first encapsulant layer 15a that covers the light-receiving surface of the solar cells 11. In this case, further low thermal expansion can be achieved for the encapsulant layer in the gap between the solar cells 11 substantially without affecting the amount of light incident on the solar cell 11 from the light-receiving-surface side. In the mode illustrated in FIG. 12, a third encapsulant layer 15c containing the fillers 50 is provided in the range where it is in alignment with the gap in the direction of the thickness of the module. Also, fillers 50 are contained in the second encapsulant layer 15b.

In the example illustrated in FIG. 12, the third encapsulant layer 15c is arranged such that it splits the first encapsulant layer 15a into two regions within the range where the third encapsulant layer 15c is in alignment with the gap between the solar cells 11 in the direction of the thickness of the module. In addition, the third encapsulant layer 15c is in direct contact with the first protection substrate 13. Meanwhile, after the third encapsulant layer 15c has been arranged in the gap between the solar cells 11, a first encapsulant layer 15a constituted by one resin substrate may be disposed between the third encapsulant layer 15c as well as the solar cells 11 and the first protection substrate 13. In this case, the first encapsulant layer 15a exists between the third encapsulant layer 15c and the first protection substrate 13.

It should be noted that a transparent glass substrate may be used as the first protection substrate 13. Although the effect will be more conspicuous when a resin substrate is used, a configuration where a glass substrate is used will exhibit the effect of suppressing the fracture of the wiring member 12.

### REFERENCE SIGNS LIST

10, 10A, 10B: solar cell module; 11: solar cell; 12, 12a: wiring member; 13: first protection substrate; 14: second protection substrate; 15: encapsulant layer; 15a: first encapsulant layer; 15b: second encapsulant layer; 15c: third encapsulant layer; 16: string; 17, 18: transition wiring member; 19: recess; 20: buffer layer; 30: reinforcing layer; 40: gas barrier layer; 50: filler

1. A solar cell module comprising:
a plurality of solar cells;
a wiring member that connects adjacent ones of the solar cells;
a first protection substrate provided on a light-receiving-surface side of the solar cells;
a second protection substrate provided on a rear-surface side of the solar cells; and
an encapsulant layer that is provided between the first protection substrate and the second protection substrate and seals the solar cells, wherein
the first protection substrate is a resin substrate, and wherein
a linear expansion coefficient (α) of the encapsulant layer is 10 to 250 (10⁻⁶/K), and a tensile modulus of elasticity (E) thereof satisfies a condition of Formula 1:
140×exp(0.005═) MPa<E (Formula 1).

2. The solar cell module according to claim 1, wherein a stiffness of the second protection substrate is higher than a stiffness of the first protection substrate, and
a linear expansion coefficient of the second protection substrate is 5 to 30 (10⁻⁶/K).

3. The solar cell module according to claim 2, wherein a thickness of the encapsulant layer between the second protection substrate and the solar cells is smaller than a thickness thereof between the first protection substrate and the solar cells.

4. The solar cell module according to claim 2, wherein a recess is formed in the second protection substrate, the recess being provided at a location where the recess is in alignment with the wiring member provided on the rear-surface side of the solar cells in a direction of a thickness of the module.

5. The solar cell module according to claim 2, further comprising a buffer layer provided between the first protection substrate and the encapsulant layer, wherein a transverse elasticity modulus of the buffer layer is 0.1 MPa or less.

6. The solar cell module according to claim 2, further comprising a reinforcing layer provided between the first protection substrate and the encapsulant layer, wherein a linear expansion coefficient of the reinforcing layer is 0 to 150 (10⁻⁶/K), a thickness of the reinforcing layer is 10 μm to 200 μm, and a total luminous transmittance of the reinforcing layer is 80% or more.

7. The solar cell module according to claim 2, further comprising a gas barrier layer provided between the first protection substrate and the encapsulant layer, wherein an oxygen permeability of the gas barrier layer is 200 cm³/m²·24 h·atm or less.

8. The solar cell module according to claim 1, wherein the tensile modulus of elasticity (E) of the encapsulant layer is less than 1000 MPa.

9. The solar cell module according to claim 1, wherein the encapsulant layer includes 1 to 30 vol % of fillers whose aspect ratio is greater than 1, and
the fillers have a modulus of elasticity of 3 GPa or more and a linear expansion coefficient of 20 ppm or less.

10. The solar cell module according to claim 9, wherein the encapsulant layer comprises a first encapsulant layer provided between the first protection substrate and the solar cell and a second encapsulant layer provided between the second protection substrate and the solar cell, and
the fillers are included in the second encapsulant layer.

11. The solar cell module according to claim 9, wherein at least one of the fillers has a length greater than a thickness of the encapsulant layer.

12. The solar cell module according to claim 9, wherein the fillers are glass fibers, and
the encapsulant layer is made of polyolefin resin.

13. The solar cell module according to claim 9, wherein the fillers are closer to the first protection substrate than the solar cells within a range where the fillers are in alignment with a gap between the adjacent ones of the solar cells in the direction of the thickness of the module.

14. A solar cell module comprising:
a plurality of solar cells;
a wiring member that connects adjacent ones of the solar cell to each other;
a first protection substrate provided on a light-receiving-surface side of the solar cells;
a second protection substrate provided on a rear-surface side of the solar cells; and
an encapsulant layer that is provided between the first protection substrate and the second protection substrate and seals the solar cells, wherein
the encapsulant layer has a linear expansion coefficient (α) of 10 to 250 (10⁻⁶/K) and a tensile modulus of elasticity (E) of the encapsulant layer satisfies a condition of Formula 1:
140×exp(0.005═) MPa<E (Formula 1).
